(19) United States
(12) Patent Application Publication
(10) Pub. No.: US 2012/0238067 A1
(43) Pub. Date: Sep. 20, 2012

(54) Methods of Fabricating Semiconductor Devices Having Gate Trenches

(76) Inventors: Won-Cheol Jeong, Yongin-si (KR); Yun-Young Yeoh, Seoul (KR); Dong-Won Kim, Seongnam-si (KR); Hong-Bae Park, Gyeyang-gu (KR); Hag-Ju Cho, Hwaseong-si (KR)

(21) Appl. No.: 13/422,223

(22) Filed: Mar. 16, 2012

(30) Foreign Application Priority Data
Mar. 18, 2011 (KR) 10-2011-0024618

(51) Int. Cl. H01L 21/336

(52) U.S. Cl. 438/301; 257/E21.433

(57) ABSTRACT

Methods of fabricating semiconductor devices including providing a substrate having a channel region defined therein; forming an insulation layer on the substrate; forming a gate trench for forming a gate electrode having a sidewall portion, a bottom portion and an edge portion between the sidewall portion and the bottom portion on the insulation layer, the gate electrode trench overlapping the channel region; and forming a gate electrode in the gate electrode trench. Forming the gate electrode includes forming a first metal layer pattern in the gate electrode trench and forming a second metal layer pattern on the first metal layer pattern.

### CROSS-REFERENCE TO RELATED APPLICATION

This application claims priority from Korean Patent Application No. 10-2011-0024618, filed Mar. 18, 2011, the contents of which are hereby incorporated herein by reference.

### FIELD

The present inventive concept generally relates to semiconductor devices and, more particularly, to methods of fabricating semiconductor devices including gate electrodes positioned in a gate trench.

### BACKGROUND

Transistors typically include a channel region between a source and a drain. A voltage is typically applied to a gate electrode between the source and drain and carriers moving along the channel region are controlled. However, with the ever increasing demands for smaller transistors, fabrication of these small devices has become difficult.

For example, in some conventional devices, a chemical vapor deposition (CVD) method is used to deposit a metal layer in a gate trench. For example, the metal layer may include TiN. However, these devices may experience problems with filling the trench and may experience high resistance. Other conventional devices use a physical vapor deposition (PVD) technique to deposit a metal layer in the gate trench. However, in these devices the metal layer may be thicker towards an upper portion of the trench causing an overhang and may become to thin near the bottom of the trench (gate edge thinning phenomenon).

### SUMMARY

Some embodiments of the present inventive concept provide methods of fabricating semiconductor devices including providing a substrate having a channel region defined therein; forming an insulation layer on the substrate; forming a gate trench in the substrate for forming a gate electrode having a sidewall portion, a bottom portion and an edge portion between the sidewall portion and the bottom portion on the insulation layer, the gate electrode trench overlapping the channel region; and forming a gate electrode in the gate electrode trench. Forming the gate electrode comprises forming a first metal layer pattern in the gate electrode trench and forming a second metal layer pattern on the first metal layer pattern.

In further embodiments, forming the insulation layer may be preceded by forming a dummy gate pattern on the substrate so as to overlap the channel region; and forming a source region on a first side of the dummy gate pattern and a drain region on a second side of the dummy gate pattern. Forming the gate electrode trench includes removing the dummy gate pattern.

In still further embodiments, the first metal layer pattern may have a first thickness on the bottom portion and a second thickness on the edge portion, the first thickness being greater than the second thickness. Forming the first metal layer pattern may include forming the first metal layer pattern using physical vapor deposition (PVD).

In some embodiments, forming the second metal layer pattern may include forming the second metal layer pattern conformally on the sidewall portion, the bottom portion and the edge portion. In certain embodiments, forming the second metal layer pattern may include forming the second metal layer pattern using one of chemical vapor deposition (CVD) and atomic layer deposition (ALD).

In further embodiments, a thickness of the second metal layer pattern may be greater than the second thickness on the edge portion.

In still further embodiments, forming the first metal layer pattern may include forming the first metal layer pattern conformally on the sidewall portion, the bottom portion and the edge portion. In certain embodiments, forming the first metal layer pattern may include forming the first metal layer pattern using one of chemical vapor deposition (CVD) and atomic layer deposition (ALD). The second metal layer pattern may include forming the second metal layer pattern using physical vapor deposition (PVD).

Some embodiments of the present inventive concept provide methods of fabricating a semiconductor device, the method including providing a substrate having a channel region defined therein; forming a dummy gate pattern on the substrate on the channel region; forming a source region on a first side of the dummy gate pattern and a drain region on a second side of the dummy gate pattern; forming an insulation layer on the substrate so as to cover the source region and the drain region; forming a gate electrode trench having a sidewall portion, a bottom portion and an edge portion between the sidewall portion and the bottom portion in the insulation layer by removing the dummy gate pattern, the gate electrode trench overlapping the channel region; and forming a gate electrode in the gate electrode trench, wherein forming a gate electrode comprises forming a first metal layer pattern in the gate electrode trench, forming a second metal layer pattern on the first metal layer pattern and forming a third metal layer pattern on the second metal layer pattern.

In further embodiments, forming the first metal layer pattern and forming the third metal layer pattern may include forming the first and third metal layer patterns using a same deposition process. Forming the second metal layer pattern may include forming the second metal layer pattern using a different deposition method process than the same deposition process used to form the first metal layer pattern and the third metal layer pattern.

In still further embodiments, forming the first and third metal layer patterns may include forming the first and third metal layer patterns using physical vapor deposition (PVD); and forming the second metal layer pattern may include forming the second metal layer pattern using one of chemical vapor deposition (CVD) and atomic layer deposition (ALD).

In some embodiments, forming the first and third metal layer patterns may include forming the first and third metal layer patterns using one of chemical vapor deposition (CVD) and atomic layer deposition (ALD); and forming the second metal layer pattern may include forming the second metal layer pattern using physical vapor deposition (PVD).

In further embodiments, a fourth metal layer pattern may be formed on the third metal layer pattern. Forming the fourth metal layer pattern may include forming the fourth metal layer pattern using a deposition process that is substantially the same as a deposition process used to form the second metal layer pattern.

Still further embodiments provide methods of fabricating a semiconductor device including providing a substrate having a channel region defined therein; forming a dummy gate pattern on the substrate on the channel region; forming a source region on a first side of the dummy gate pattern and a drain region on a second side of the dummy gate pattern; forming an insulation layer on the substrate so as to cover the source and drain regions; forming a gate electrode trench having a sidewall portion, a bottom portion and an edge portion between the sidewall portion and the bottom portion on the insulation layer by removing the dummy gate pattern, the gate electrode trench overlapping the channel region; and forming a gate electrode in the gate electrode trench. Forming the gate electrode includes forming a first metal layer pattern in the gate electrode trench by one of physical vapor deposition (PVD), chemical vapor deposition (CVD) and atomic layer deposition (ALD), and forming a second metal layer pattern on the first metal layer pattern using one of PVD, CVD and ALD.

In some embodiments, a third metal layer pattern is formed on the second metal layer pattern using one of PVD, CVD and ALD.

In further embodiments, a fourth metal layer pattern is formed on the third metal layer pattern using one of PVD, CVD and ALD.

### BRIEF DESCRIPTION OF THE DRAWINGS

The above and other features and advantages of the present inventive concept will become more apparent by describing in detail preferred embodiments thereof with reference to the attached drawings in which:

FIG. 1 is a cross-section of a semiconductor device according to some embodiments of the present inventive concept.

FIG. 2 is a flowchart illustrating processing steps in the fabrication of a semiconductor device according to some embodiments of the present inventive concept.

FIGS. 3 through 14 are cross-sections illustrating processing steps in the fabrication of semiconductor devices in accordance with some embodiments of the present inventive concept.

FIG. 15 is a graph illustrating work function characteristic of a metal layer in accordance with some embodiments of the present inventive concept.

FIG. 16 is a cross-section of a semiconductor device according to some embodiments of the present inventive concept.

FIG. 17 through 19 are cross-sections illustrating processing steps in the fabrication of semiconductor devices according to some embodiments of the present inventive concept.

FIG. 20 is a cross-section of a semiconductor device according to some embodiments of the present inventive concept.

FIG. 21 is a cross-section of a semiconductor device according to some embodiments of the present inventive concept.

FIG. 22 is a flowchart illustrating processing steps in the fabrication of the semiconductor device illustrated in FIG. 21 in accordance with some embodiments of the present inventive concept.

FIG. 23 is a cross-section of a semiconductor device in accordance with some embodiments of the present inventive concept.

FIG. 24 is a cross-section of a semiconductor device in accordance with some embodiments of the present inventive concept.

FIG. 25 is a flowchart illustrating processing steps in the fabrication of a semiconductor device in accordance with some embodiments of the present inventive concept.

### DETAILED DESCRIPTION OF EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the inventive concept (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. As used herein, the term “and/or” includes any and all combinations of one or more of the associated listed items.

Unless defined otherwise, all technical and scientific terms used herein have the same meaning as commonly understood by one of ordinary skill in the art to which this inventive concept belongs. It is noted that the use of any and all examples, or exemplary terms provided herein is intended merely to better illuminate the inventive concept and is not a limitation on the scope of the inventive concept unless otherwise specified. Further, unless defined otherwise, all terms defined in generally used dictionaries may not be overly interpreted.

The present inventive concept will be described with reference to perspective views, cross-sections, and/or plan views, in which preferred embodiments of the inventive concept are shown. Thus, the profile of an exemplary view may be modified according to manufacturing techniques and/or allowances. That is, the embodiments of the inventive concept are not intended to limit the scope of the present inventive concept but cover all changes and modifications that can be caused due to a change in manufacturing process. Thus, regions shown in the drawings are illustrated in schematic form and the shapes of the regions are presented simply by way of illustration and not as a limitation.

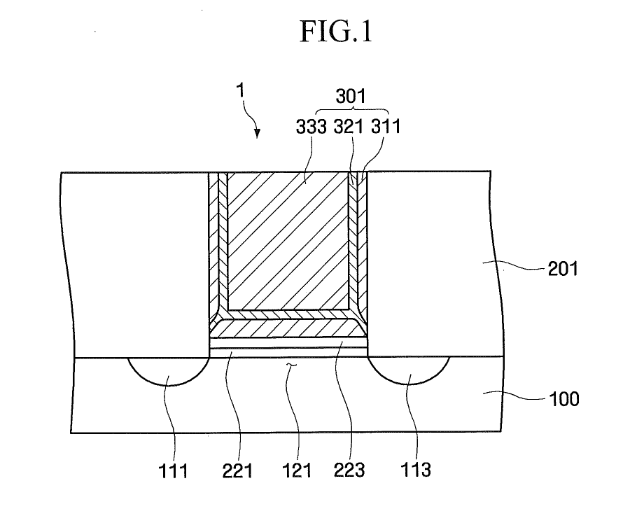

Methods of fabricating semiconductor devices according to some embodiments of the present inventive concept will now be discussed with respect to FIGS. 1 through 15. Referring first to FIG. 1, a cross-section of a semiconductor device fabricated according to some embodiments of the present inventive concept will be discussed.

As illustrated in FIG. 1, the semiconductor device 1 includes a semiconductor substrate 100, a source region 111, drain region 113, a channel region 121, an insulation layer 201, a gate insulation layer 221, a capping layer 223 and a gate electrode 301.

The semiconductor substrate 100 may be a silicon substrate, silicon on insulator (SOI) substrate, a gallium arsenide substrate, a silicon germanium substrate, or the like. The semiconductor substrate 100 may have a first conductivity type or a second conductivity type. For example, the semiconductor substrate 100 may have a p-type or n-type conductivity type without departing from the scope of the present application.

A portion of the semiconductor substrate 100 overlapping a lower portion of the gate electrode 301 is defined as a channel region 121. The channel region 121 may function as a passageway of carriers when a bias voltage is applied to the gate electrode 301. For example, if the semiconductor device 1 is a p-type metal oxide semiconductor (PMOS) device, the channel region 121 may be used as a passageway of holes. If, on the other hand, the semiconductor device 1 is an n-type metal oxide semiconductor (NMOS) device, the channel region 121 may be used as a passageway of electrons.

The source region 111 and the drain region 113 are provided at both sides of the channel region 121. The source region 111 and the drain region 113 may be regions doped with impurities in higher concentrations than the semiconductor substrate 1. For example, if the semiconductor device 1 is a PMOS device, boron (B), gallium (Ga) or indium (In) located in Group III in the periodic table may be doped into the source region 111 and the drain region 113. However, if the semiconductor device 1 is an NMOS device, nitrogen (N) or arsenic (As) located in Group V in the periodic table may be doped into the source region 111 and the drain region 113.

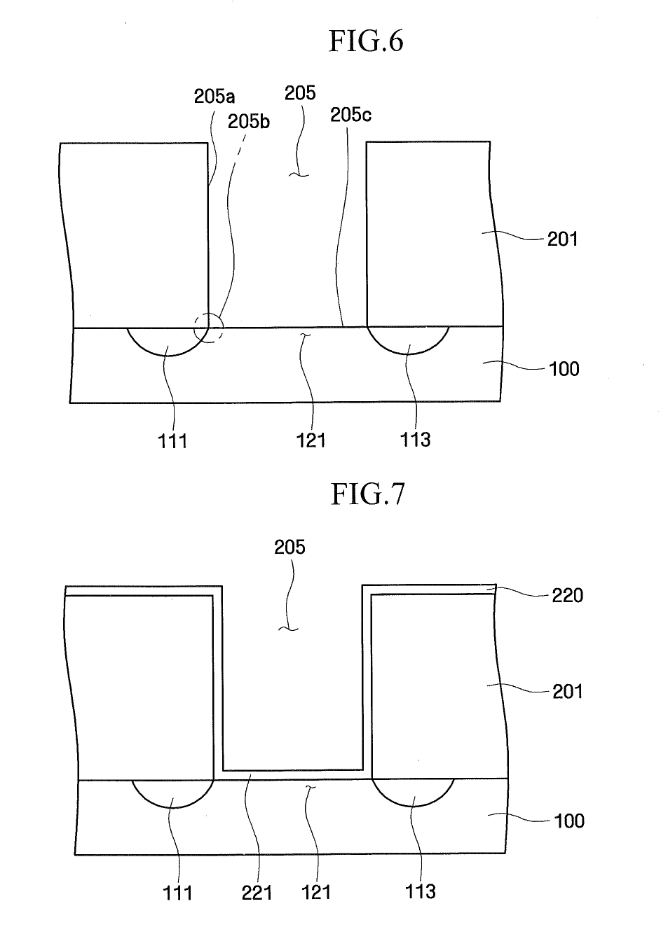

The insulation layer 201 may be provided on the semiconductor substrate 100. The insulation layer 201 may include a silicon oxide (SiOₓ) layer made of, for example, Flowable Oxide (FOX), Tonen SilaZene (TOSZ), Undoped Silicate Glass (USG), Boro Silicate Glass (BSG), Phospho Silicate Glass (PSG), BoroPhospho Silicate Glass (BPSG), Plasma Enhanced Tetra Ethyl Ortho Silicate (PE-TEOS), Fluoride Silicate Glass (FSG), or high density plasma (HDP). A gate electrode trench (205 of FIG. 6) may be provided on the insulation layer 201. The gate electrode 301 may be positioned in the gate trench 205. The trench 205 in the insulation layer 201 may be used as a mold for forming the gate electrode 301. The gate electrode trench 205 may overlap the channel region 121 of the semiconductor substrate 100.

The gate insulation layer 221 may be positioned on the semiconductor substrate 100 so as to overlap the channel region 121 defined in the semiconductor substrate 100. The gate insulation layer 221 is formed for the purpose of insulating the channel region 121 and the gate electrode 301 formed on the semiconductor substrate 100. The gate insulation layer 221 may be a thermal oxide layer or an SiOₓ layer made of, for example, FOX, TOSZ, US, BSG, PSG, BPSG, PE-TEOS, FSG, or HDP.

In some embodiments, the gate insulation layer 221 may be made of a relatively high dielectric constant (high-k) material capable of reducing the likelihood of leakage current such as a cross talk. For example, the high-k material may be, for example, hafnium dioxide (HfO₂) or zirconium dioxide (ZrO₂).

The capping layer 223 may be positioned on the gate insulation layer 221. The capping layer 223 may be positioned between the gate insulation layer 221 and a gate electrode 301. The capping layer 223 may reduce the likelihood, or possibly prevent, conductive materials contained in the gate electrode 301 from being diffused into the gate insulation layer 221. In other words, the capping layer 223 reduces the likelihood, or possibly prevents, the gate insulation layer 221 from deteriorating to reduce the likelihood, or possibly prevent, leakage current from being generated in the semiconductor device 1, thereby achieving the stability and reliability of the semiconductor device 1. The capping layer 223 may include, for example, TaN, or TiN.

The gate electrode 301 may be positioned on the semiconductor substrate 100. In some embodiments, the gate electrode 301 may include a first metal layer pattern 311, a second metal layer pattern 321 and a gate electrode 333. The gate electrode 301 may be positioned within the gate electrode trench 205 of the insulation layer 201.

The first metal layer pattern 311 may have a work function of the semiconductor device 1 according to a design rule. In other words, the work function of the semiconductor device 1 may determine a threshold voltage of a transistor. As a work function is closer to a band edge, an amount of dopant implanted into the channel region 121 is reduced, thereby increasing carrier mobility. Consequently, the overall operating characteristics of a transistor in the semiconductor device 1 can be improved.

A PMOS transistor, for example, has a band edge of about 5.17 eV, which may, however, vary according to the design rule. Thus, if the semiconductor device 1 includes a PMOS transistor, the first metal layer pattern 311 may be formed from a material having a work function of approximately 5.17 eV. However, an NMOS transistor has a band edge of approximately 4.05 eV. Thus, if the semiconductor device 1 includes an NMOS transistor, the first metal layer pattern 311 may be formed from a material having a work function of approximately 4.05 eV.

For example, assuming that the semiconductor device 1 includes a PMOS transistor, the first metal layer pattern 311 may be made from titanium nitride (TiN) for the reason stated above using a physical vapor deposition (PVD) method.

If the first metal layer pattern 311 is formed using PVD, in view of PVD property, it may have different thicknesses on a bottom portion (205c of FIG. 6) and an edge portion (205b of FIG. 6) of the gate electrode trench 205, which will be discussed below with respect to FIG. 6.

The second metal layer pattern 321 may be positioned on the first metal layer pattern 311. The second metal layer pattern 321 may supplement a thickness of the first metal layer pattern 311.

As discussed above, the first metal layer pattern 311 may be formed having different thicknesses on the bottom portion 205c and the edge portion 205b of the gate electrode trench 205. Specifically, the thickness of the first metal layer pattern 311 may be smaller on the edge portion 205b than on the bottom portion 205c. That is to say, a gate edge thinning phenomenon in which the edge of the gate electrode 301 is thinned may occur in the gate electrode trench 205.

Accordingly, a work function close to the band edge may not be obtained in the edge portion 205b. Thus, the overall operating characteristics of the transistor in the semiconductor device 1 may deteriorate. In addition, conductive material of the gate electrode 301 may be diffused into the capping layer 223 or the gate insulation layer 221 through the edge portion 205b, thereby deteriorating the gate insulation layer 221. In this regard, it is necessary to supplement the thickness of the edge portion 205b. That is to say, the second metal layer pattern 321 is additionally formed on the first metal layer pattern 311 to address the problem of the gate edge thinning phenomenon.

Meanwhile, assuming that the semiconductor device 1 includes a PMOS transistor, the second metal layer pattern 321 may be made from titanium nitride (TiN) using a chemical vapor deposition (CVD). Compared to the PVD, the CVD allows a layer to be conformally formed. Thus, the second metal layer pattern 321 may be uniformly formed up to the edge portion 205b in the gate electrode trench 205.

The gate electrode 333 is positioned on the second metal layer pattern 321. The gate electrode 333 may include, for example, poly-Si, poly-SiGe, a metal such as Al, Ta, TaN, TaSiN, Mo, Ru, Ni, or NiSi, or combinations thereof.

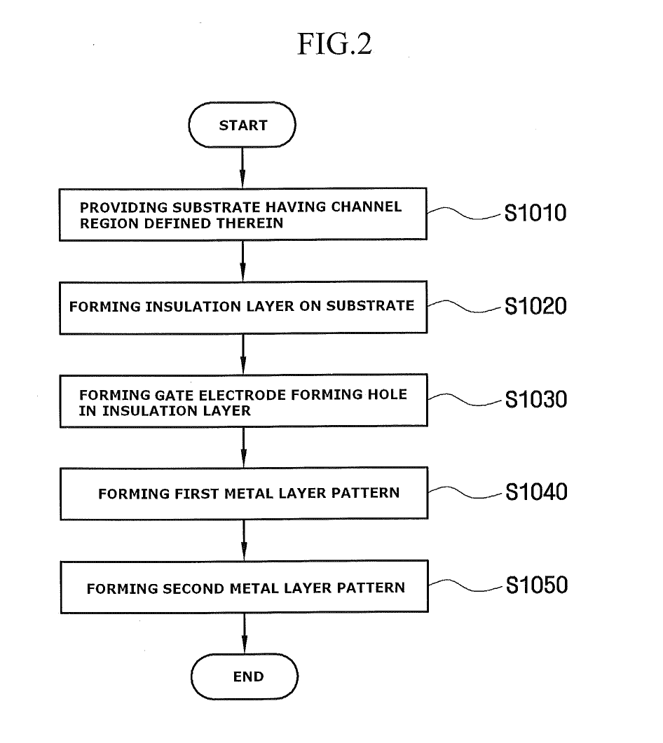

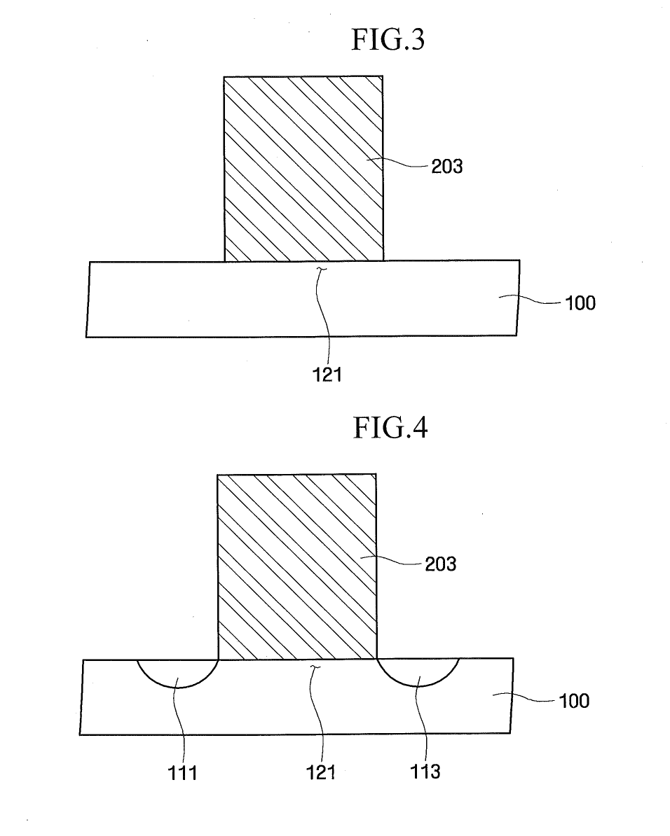

Referring now to FIGS. 2-15, processing steps in the fabrication of the semiconductor device illustrated in FIG. 1 will be discussed. FIG. 2 is a flowchart illustrating processing steps in the fabrication of a semiconductor device in accordance with some embodiments of the present inventive concept. FIGS. 3 to 14 are cross-sections illustrating processing steps in the fabrication of a semiconductor device according some embodiments of the present inventive concept. FIG. 15 is a graph illustrating a work function characteristic of a metal layer. The same reference numerals denote the same elements illustrated in FIG. 1 and, thus, details with respect to the elements discussed above with respect to FIG. 1 may not be repeated herein.

Referring first to FIGS. 2 and 3, a semiconductor substrate 100 having a channel region 121 defined therein is provided (S1010). A dummy gate pattern 203 is formed on the semiconductor substrate 100. The dummy gate pattern 203 may be formed by forming a layer (not shown) for forming a dummy gate pattern using polysilicon (poly-Si) through a CVD process and then patterning the gate pattern forming layer according to a predetermined design rule. The channel region 121 may be defined as a partial region of the semiconductor substrate 100 overlapping the dummy gate pattern 203 formed on the semiconductor substrate 100.

Before forming the dummy gate pattern 203, a gate insulation layer forming layer and a capping layer forming layer are formed on the semiconductor substrate 100, and a gate pattern forming layer is formed, followed by simultaneously patterning, thereby forming a gate insulation layer 221, a capping layer 223 and a dummy gate pattern 203.

Referring now to FIG. 4, impurities are implanted into the substrate 100 on both sides of the dummy gate pattern 203 to form a source region 111 and a drain region 113. When the semiconductor device 1 includes a PMOS transistor, an element in Groups III of the periodic table, such as boron (B), gallium (Ga) or indium (In), may be implanted into the semiconductor substrate 100 on both sides of the dummy gate pattern 203. On the other hand, when the semiconductor device 1 includes an NMOS transistor, an element in Groups V of the periodic table, such as nitrogen (N), phosphorus (P) or arsenic (As), may be implanted into the semiconductor substrate 100 on both sides of the dummy gate pattern 203.

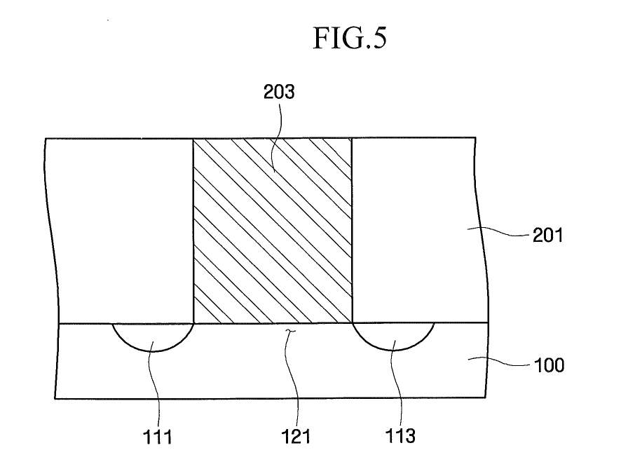

Referring to now to FIG. 5, an insulation layer 201 is formed on the dummy gate pattern 203 and the semiconductor substrate 100 (S1020). The insulation layer 201 is formed on the entire surface of the semiconductor substrate 100 using silicon oxide (SiOx) through a CVD process. Accordingly, the dummy gate pattern 203 may be covered by the insulation layer 201. The insulation layer 201 is planarized to expose a top surface of the dummy gate pattern 203. In particular, the insulation layer 201 is planarized to expose an upper surface of the dummy gate pattern 203 using, for example, a chemical mechanical polishing (CMP) process.

Referring now to FIG. 6, the dummy gate pattern 203 in the insulation layer 201 is completely removed. Accordingly, the channel region 121 of the semiconductor substrate 100 may be exposed to the outside. If the capping layer 223 or the gate insulation layer 221 is formed on the semiconductor substrate 100, one of the capping layer 223 and the gate insulation layer 221 may be exposed to the outside.

A gate electrode trench 205 is formed at a region of the insulation layer 201 from which the dummy gate pattern 203 has been removed (S1030). The gate electrode trench 205 is provided on the channel region 121 of the semiconductor substrate 100, and may have a sidewall portion 205a, a bottom portion 205c, and an edge portion 205b between the sidewall portion 205a and the bottom portion 205c. The sidewall portion 205a may be part of the insulation layer 201, the bottom portion 205c may be part of the semiconductor substrate 100, and the edge portion 205b may be parts of the insulation layer 201 and the semiconductor substrate 100.

Referring now to FIG. 7, a gate insulation layer forming layer 220 is conformally formed on the insulation layer 201 and in the gate electrode trench 205. The gate insulation layer forming layer 220 may be formed on the insulation layer 201 and in the gate electrode trench 205 using, for example, hafnium dioxide (HfO₂), which is a high-k material, using a CVD process.

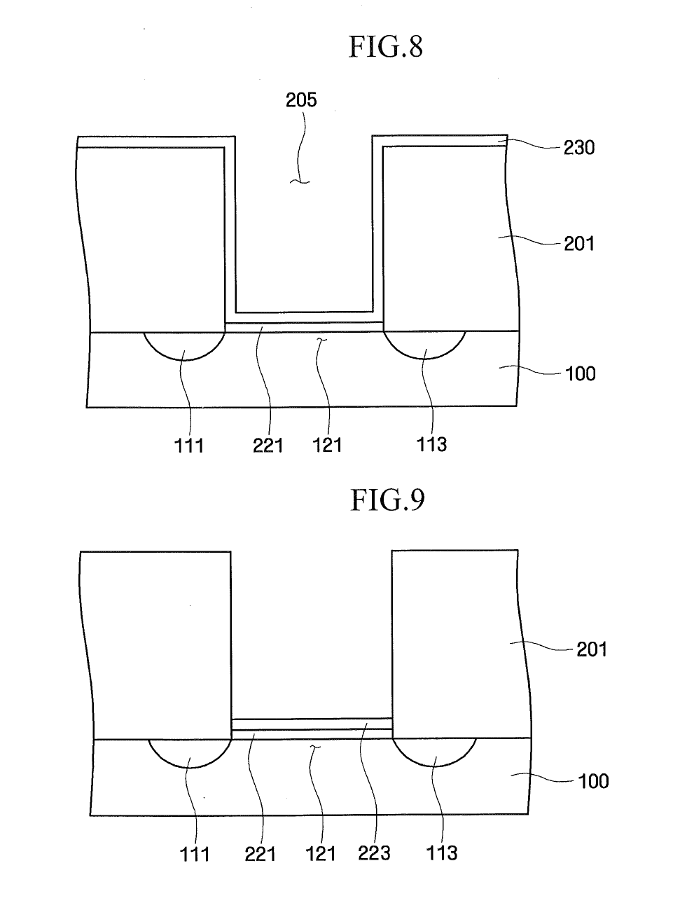

Referring now to FIG. 8, the gate insulation layer forming layer 220 is patterned to form a gate insulation layer 221. The gate insulation layer forming layer 220 in the gate electrode trench 205 and on the insulation layer 201 is removed, except for part of the gate insulation layer forming layer 220 on the bottom portion 205c of the gate electrode trench 205.

A capping layer forming layer 230 is conformally formed on the gate insulation layer 221, the insulation layer 201 and in the gate electrode trench 205. The capping layer forming layer 230 is formed on the entire surface of the insulation layer 201 and the gate electrode trench 205 using, for example, TaN, using a CVD process.

Referring now to FIG. 9, the capping layer forming layer 230 is patterned to form a capping layer 223. In these embodiments, the gate electrode trench 205, the insulation layer 201 and the capping layer forming layer 230 are removed, except for part of the capping layer forming layer 230 on the bottom portion 205c of the gate electrode trench 205.

As discussed above, the gate insulation layer 221 and the capping layer 223 may be formed in turn. Alternatively, although not shown, the gate insulation layer forming layer 220 and the capping layer forming layer 230 are formed in turn, and then simultaneously patterned to form the gate insulation layer 221 and the capping layer 223 simultaneously. Meanwhile, as discussed above, before forming the dummy gate pattern 203, the gate insulation layer 221 and the capping layer 223 may be formed. In these embodiments, the processing step discussed above with respect to FIGS. 7 through 9 may be omitted.

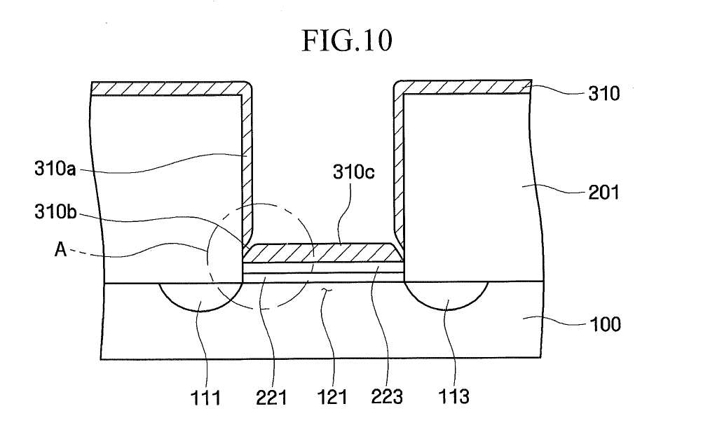

Referring now to FIG. 10, a first metal layer 310 is formed on the gate insulation layer 221, the gate electrode trench 205 and the capping layer 223. The first metal layer 310 may be formed on the entire surface of the insulation layer 201 and the gate electrode trench 205 using, for example, titanium nitride (TiN), through a PVD process. Examples of the PVD process may include a sputtering process or an E-beam process. In the following description, for the sake of convenient explanation, it is assumed that the first metal layer 310 is formed using a sputtering process. The first metal layer 310 is patterned in a subsequent process to become a first metal layer pattern 311.

As discussed above, in order for the semiconductor device 1 to demonstrate operating characteristics in conformity with the design rule, the first metal layer 310 should have a work function required for the semiconductor device 1.

For example, if the semiconductor device 1 is a PMOS device, which has a band edge of approximately 5.17 eV, the first metal layer 310 may be formed from a material having a work function of approximately 5.17 eV. Referring to FIG. 15, if a metal layer a1 is formed using titanium nitride (TiN) through a PVD process, the work function is slightly changed according to the thickness of the metal layer a1, but may be in a range of from about 5.05 eV to about 5.1 eV.

However, if a metal layer a2 is formed using titanium nitride (TiN) through a CVD process, the work function is slightly changed according to the thickness of the metal layer a2, but may be in a range of from about 4.8 eV to about 5.0 eV. Thus, as is clear from the result stated above, in order for the first metal layer 310 to have a work function of approximately 5.17 eV, the first metal layer 310 may be formed from titanium nitride (TiN) through a PVD process.

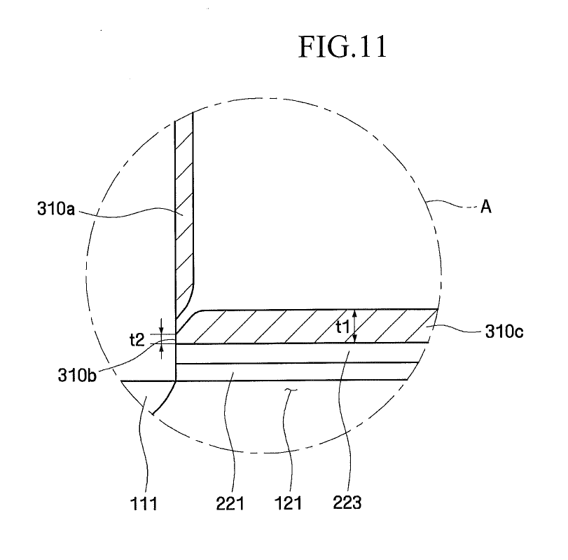

Referring now to FIGS. 10 and 11, the first metal layer 310 may be formed on a sidewall portion 205a, an edge portion 205b and a bottom portion 205c of the gate electrode trench 205. The first metal layer 310 may have different thicknesses on an edge portion 205b and a bottom portion 205c of the gate electrode trench 205. For example, assuming that the first metal layer 310 has a first thickness t1 on the bottom portion 205c and a second thickness t2 on the edge portion 205b, the first thickness t1 on the bottom portion 205c may be greater than the second thickness t2 on the edge portion 205b, which may attribute to processing properties of a PVD process. In other words, the PVD process is highly directional compared to the CVD process. Accordingly, use of the PVD process may allow the first metal layer 310 to be relatively thinly formed on the edge portion 205b of the gate electrode trench 205.

In order to increase the thickness of the first metal layer 310 formed on the edge portion 205b, the directionality of the PVD process may be decreased, possibly resulting in an overhang phenomenon in which the first metal layer 310 is formed relatively thick on the gate electrode trench 205. Thus, a gap-fill property with respect to the gate electrode trench 205 may deteriorate, and voids may be formed in a gate electrode 333 to be formed in a subsequent process. Accordingly, the overall operating characteristics of the semiconductor device 1 may deteriorate.

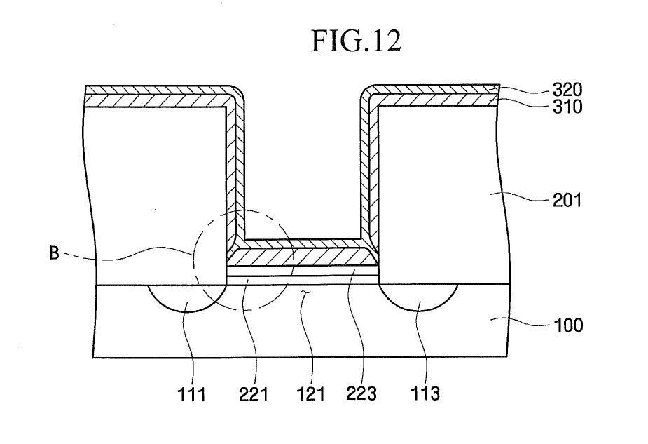

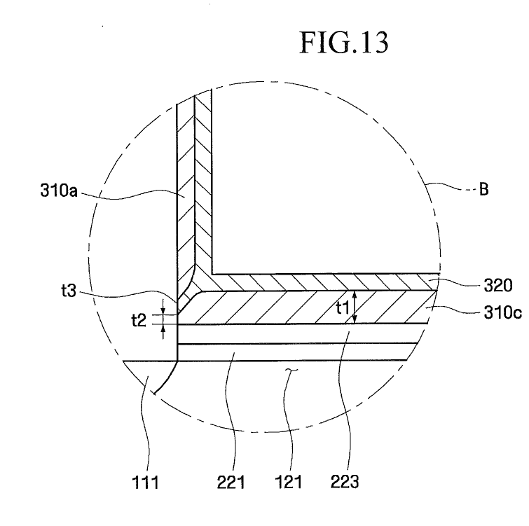

Referring to FIGS. 12 and 13, the second metal layer 310 may be conformally formed on the sidewall portion 205a, the edge portion 205b and the bottom portion 205c in the gate electrode trench 205. For example, the second metal layer 320 may be formed using titanium nitride (TiN) through a CVD process or an atomic layer deposition (ALD) process.

The second metal layer 320 may be formed on the first metal layer 310 of the edge portion 205b. In these embodiments, the second metal layer 320 may have a thickness greater than the second thickness t2 of the first metal layer 310 of the edge portion 205b. Accordingly, a thickness of the second metal layer pattern 321 formed by patterning the second metal layer 320 is also greater than the second thickness t2 of the first metal layer pattern 311 of the edge portion 205b. Therefore, the problem of the gate edge thinning phenomenon, which may occur in the edge portion 205b, can possibly be overcome.

According to some embodiments of the present inventive concept, the likelihood of an overhang and gate edge thinning can be reduced, or possibly prevented, while achieving the work function of a transistor in conformity with the design rule of the semiconductor device 1. Accordingly, the operating characteristic of the semiconductor device 1 can be improved.

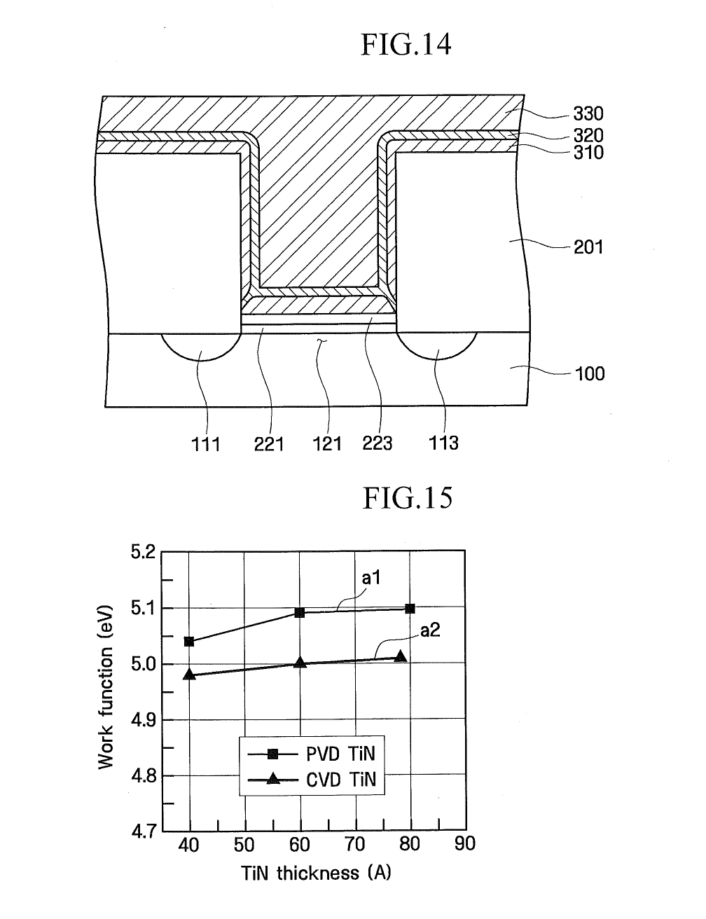

Referring now to FIG. 14, a gate electrode forming layer 330 is formed on the resultant structure illustrated in FIG. 12. The gate electrode forming layer 330 may be formed to fill the gate electrode trench 205. For example, the gate electrode forming layer 330 may be formed using aluminum (Al) through a CVD process.

Referring to FIGS. 1 and 14, the first metal layer 310, the second metal layer 320 and the gate electrode forming layer 330 are patterned to form a first metal layer pattern 311, a second metal layer pattern 321 and a gate electrode 333, respectively (S1040 and S1050).

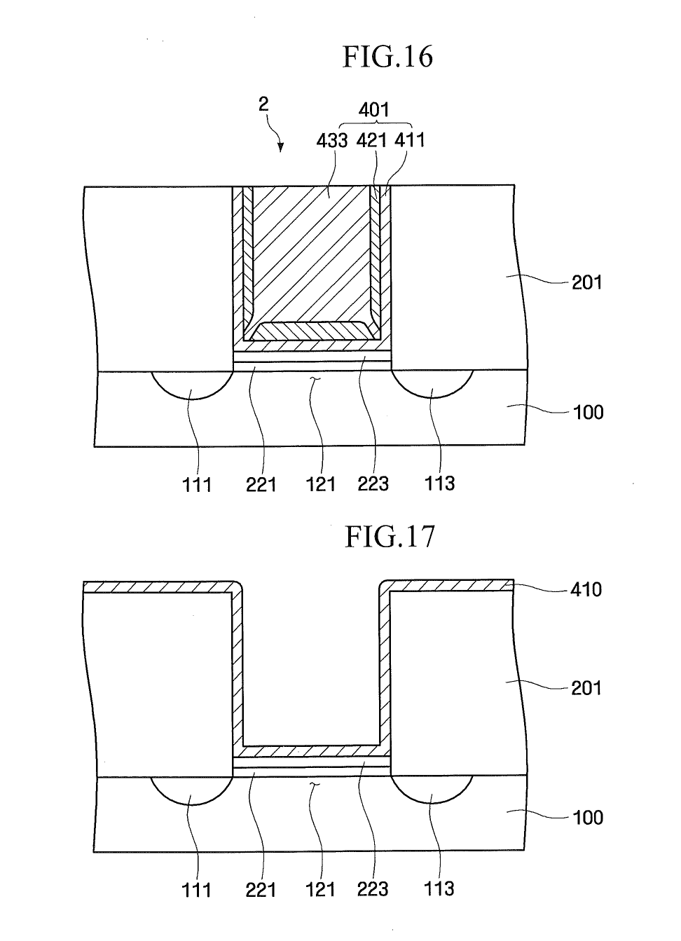

Processing steps in the fabrication of semiconductor devices according to some embodiments of the present inventive concept will be described with reference to FIGS. 2 and 16 to 19. FIG. 16 is a cross-section of a semiconductor device in accordance with some embodiments of the present inventive concept and FIGS. 17 through 19 are cross-sections illustrating processing steps in the fabrication of semiconductor devices in accordance with some embodiments of the present inventive concept. For the sake of convenient explanation, the same reference numerals denote the same elements throughout and, thus, details of elements discussed above may not be repeated herein in the interest of brevity.

Referring now to FIG. 16, the semiconductor device 2 includes a semiconductor substrate 100, a source region 111, a drain region 113, a channel region 121, an insulation layer 201, a gate insulation layer 221, a capping layer 223 and a gate electrode 401.

The gate electrode 401 may be positioned on the semiconductor substrate 100. The gate electrode 401 may include a first metal layer pattern 411, a second metal layer pattern 421 and a gate electrode 433. The gate electrode 401 may be positioned in the gate electrode trench 205 of the insulation layer 201.

The first metal layer pattern 411 may be conformally formed in the gate electrode trench 205. Thus, the first metal layer pattern 411 may also be formed on the edge portion (205b of FIG. 6) in the gate electrode trench 205. Accordingly, the likelihood of a gate edge thinning phenomenon in which an edge of the gate electrode 401 is thinned in the gate electrode trench 205 can be reduces, or possibly prevented. The first metal layer pattern 411 may be formed using titanium nitride (TiN) through a CVD process. In other words, the first metal layer pattern 411 can perform substantially the same function as the second metal layer pattern 321 discussed above.

A second metal layer pattern 421 may be positioned on the first metal layer pattern 411. The second metal layer pattern 421 may have a work function of the semiconductor device 2 in conformity with the design rule of the semiconductor device 1. A threshold voltage of a transistor in the semiconductor device 1 can be determined by the work function. As a work function is closer to a band edge, an amount of dopant implanted into the channel region 121 is reduced, thereby increasing carrier mobility. Consequently, the overall operating characteristics of a transistor in the semiconductor device 2 can be improved.

A PMOS transistor, for example, has a band edge of approximately 5.17 eV, which may, however, vary according to the design rule. Thus, if the semiconductor device 2 includes a PMOS transistor, the second metal layer pattern 421 may be formed from a material having a work function of approximately 5.17 eV. However, an NMOS transistor has a band edge of approximately 4.05 eV. Thus, if the semiconductor device 1 includes an NMOS transistor, the second metal layer pattern 421 may be formed from a material having a work function of approximately 4.05 eV.

For example, assuming that the semiconductor device 2 includes a PMOS transistor, the second metal layer pattern 421 may be made from titanium nitride (TiN) for the reason stated above using a PVD process.

A gate electrode 433 is positioned on the second metal layer pattern 421. The gate electrode 433 may include, for example, poly-Si, poly-SiGe, a metal such as Al, Ta, TaN, TaSiN, Mo, Ru, Ni, or NiSi, or any combination thereof.

Processing steps in the fabrication of semiconductor devices in accordance with these embodiments of the present inventive concept will be discussed with respect to FIGS. 2 and 17 through 19.

Referring now to FIGS. 2 and 9, the semiconductor substrate 100 having the channel region 121 defined therein is provided (S1010), and the insulation layer 201 is formed on the semiconductor substrate 100 (S1020). The gate electrode trench 205 is formed in the insulation layer 201 (S1030). Since the above-stated processes are substantially the same as those discussed above, details thereof will not be repeated herein.

Referring now to FIG. 17, the first metal layer 410 may be conformally formed on the sidewall portion 205a, the edge portion 205b and the bottom portion 205c in the gate electrode trench 205. For example, the first metal layer 310 may be formed using titanium nitride (TiN) through a CVD process or an atomic layer deposition (ALD) process. The first metal layer 410 is patterned in a subsequent process to become a first metal layer pattern 411.

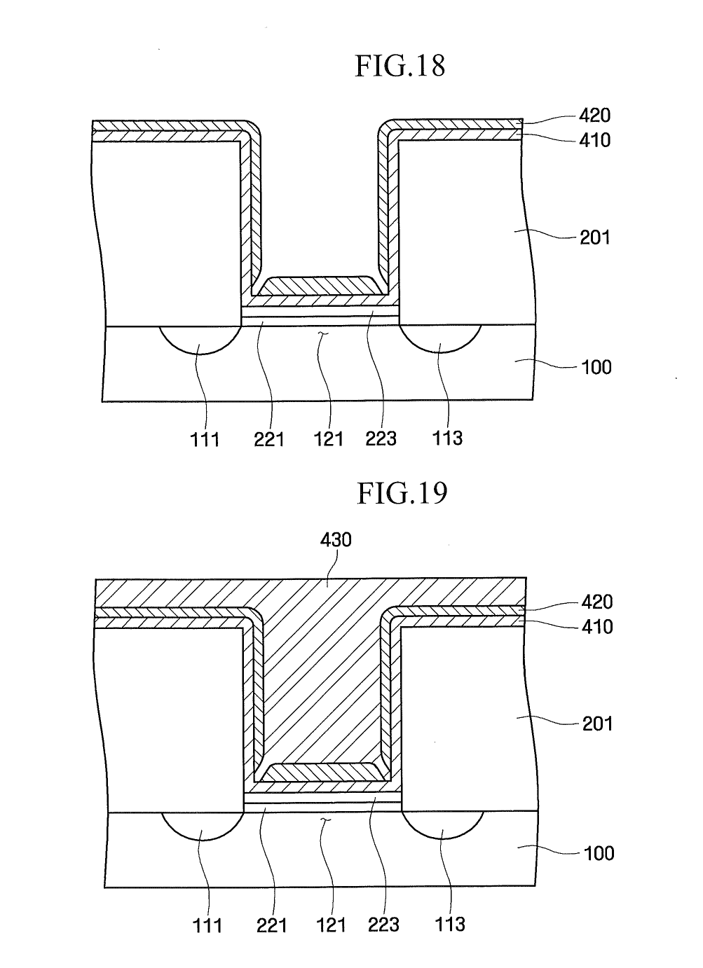

Referring now to FIG. 18, a second metal layer 420 is formed on the first metal layer 410. The second metal layer 420 may be formed on the entire surface of the first metal layer 410 using titanium nitride (TiN) through a PVD process. Examples of the PVD process may include a sputtering process or an E-beam process. In the following description, for the sake of convenient explanation, it is assumed that the second metal layer 420 is formed using a sputtering process. The second metal layer 420 is patterned in a subsequent process to become a second metal layer pattern 421.

Referring now to FIG. 19, a gate electrode forming layer 430 is formed on the resultant structure illustrated in FIG. 18. In these embodiments, the gate electrode forming layer 430 may be formed to fill the gate electrode trench 205. For example, the gate electrode forming layer 430 may be formed using aluminum (Al) through a CVD process.

Referring to FIGS. 19 and 16, the first metal layer 410, the second metal layer 420 and the gate electrode forming layer 430 are patterned to form a first metal layer pattern 411, a second metal layer pattern 421 and a gate electrode 433, respectively (S1040 and S1050).

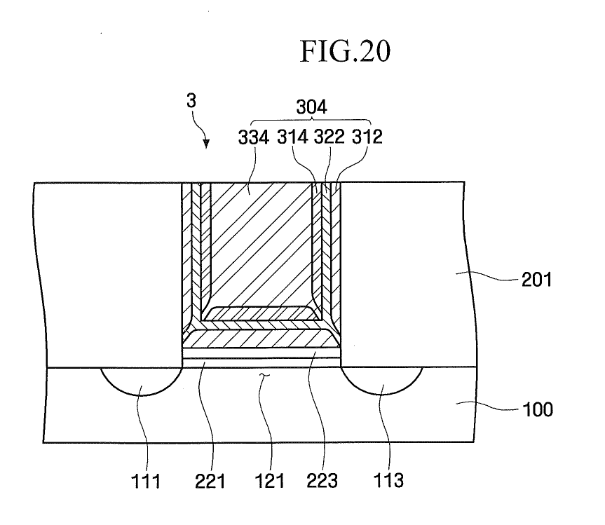

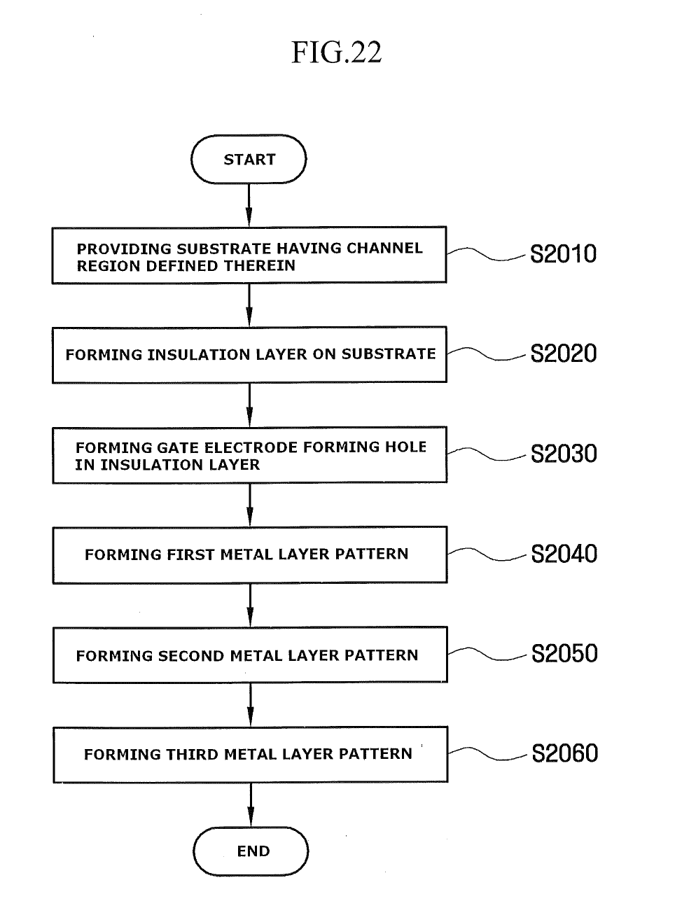

Processing steps in the fabrication of semiconductor devices in accordance with some embodiments of the present inventive concept will be described with reference to FIGS. 20 and 22. FIG. 20 is a cross-section of a semiconductor device according to some embodiments of the present inventive concept, and FIG. 22 is a flowchart illustrating processing steps in the fabrication of semiconductor devices in accordance with some embodiments of the present inventive concept. For the sake of convenient explanation, the same reference numerals refer to the same elements throughout and, thus, details of like elements will not be repeated herein in the interest of brevity.

Processing steps in the fabrication of semiconductor devices in accordance with these embodiments are similar to those discussed above.

Referring now to FIG. 22, the processing steps S2010 to S2050 are substantially the same as S1010 to S1050 discussed above.

Referring to FIGS. 20 and 22, the semiconductor device 3 may include a semiconductor substrate 100, a source region 111, a drain region 113, a channel region 121, an insulation layer 201, a gate insulation layer 221, a capping layer 223 and a gate electrode 304. In the semiconductor device 3, the gate electrode 304 may include a first metal layer pattern 312, a second metal layer pattern 322 formed on the first metal layer pattern 312, and a third metal layer pattern 314 formed on the second metal layer pattern 322. In other words, the third metal layer pattern 314 may be formed on the second metal layer pattern 322 (S2060). In these embodiments, he first metal layer pattern 312 and the second metal layer pattern 322 are substantially the same as first metal layer pattern 311 and the second metal layer pattern 321 discussed above, respectively.

The third metal layer pattern 314 may be formed on the second metal layer pattern 322 using, for example, titanium nitride (TiN), through a PVD process. The third metal layer pattern 322 may have a work function of the semiconductor device 3 according to the design rule. The work function of the semiconductor device 3 may determine a threshold voltage of a transistor. As a work function is closer to a band edge, an amount of dopant implanted into the channel region 121 is reduced, thereby increasing carrier mobility. Consequently, the overall operating characteristics of a transistor in the semiconductor device 3 can be improved.

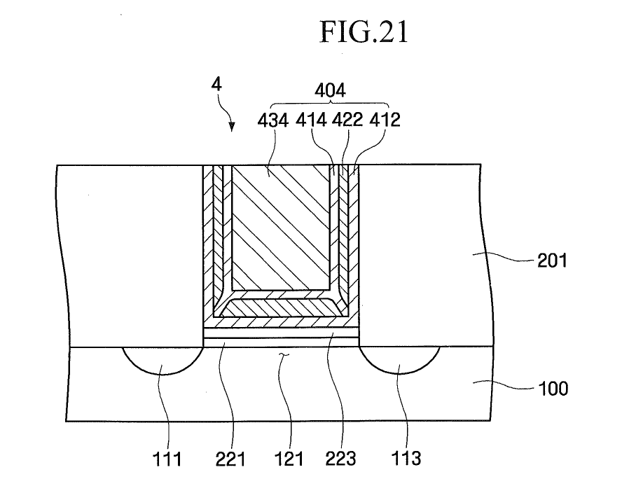

Processing steps in the fabrication of semiconductor devices in accordance with some embodiments of the present inventive concept will be discussed with respect to FIGS. 21 and 22. FIG. 21 is a cross-section of a semiconductor device in accordance with some embodiments of the present inventive concept, and FIG. 22 is a flowchart illustrating processing steps in the fabrication of semiconductor devices in accordance with some embodiments of the present inventive concept. For the sake of convenient explanation, the same reference numerals refer to the same elements throughout and, thus, details of these elements will not be repeated herein in the interest of brevity. Processing steps in the fabrication of semiconductor devices in accordance with these embodiments of the present inventive concept are substantially the same as those discussed above. In particular, referring to FIG. 22, processing steps S2010 to S2050 are substantially the same as S1010 to S1050 discussed above.

Referring now to FIGS. 21 and 22, the semiconductor device 4 may include a semiconductor substrate 100, a source region 111, a drain region 113, a channel region 121, an insulation layer 201, a gate insulation layer 221, a capping layer 223 and a gate electrode 404. In the semiconductor device 4, the gate electrode 404 may include a first metal layer pattern 412, a second metal layer pattern 422 formed on the first metal layer pattern 412, and a third metal layer pattern 414 formed on the second metal layer pattern 422. That is to say, the third metal layer pattern 414 may be formed on the second metal layer pattern 422 (S2060). In these embodiments, the first metal layer pattern 412 and the second metal layer pattern 422 are substantially the same as first metal layer pattern 411 and the second metal layer pattern 421 discussed above, respectively.

The third metal layer pattern 414 may be conformally formed on the first and second metal layer patterns 412 and 422. Accordingly, the third metal layer pattern 414 may also be formed on the first metal layer pattern 412 on an edge portion (205b of FIG. 6) in the gate electrode trench 205. Accordingly, the likelihood of a gate edge thinning phenomenon in which an edge of the gate electrode 404 is thinned in the gate electrode trench 205 can be reduced, or possibly prevented. The third metal layer pattern 414 may be formed using titanium nitride (TiN) through a CVD process.

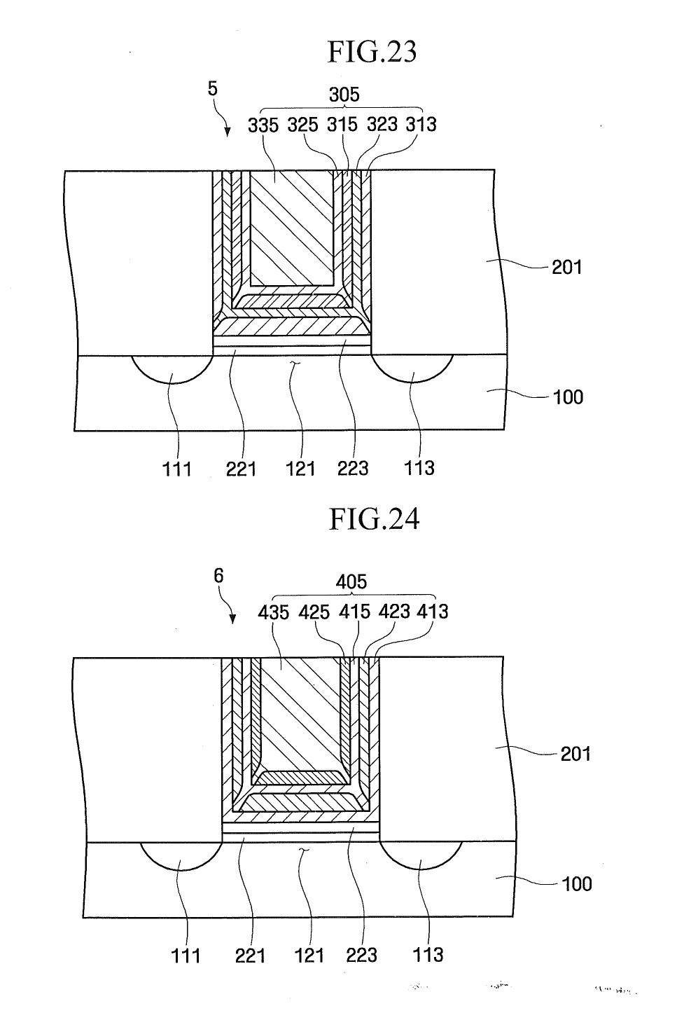

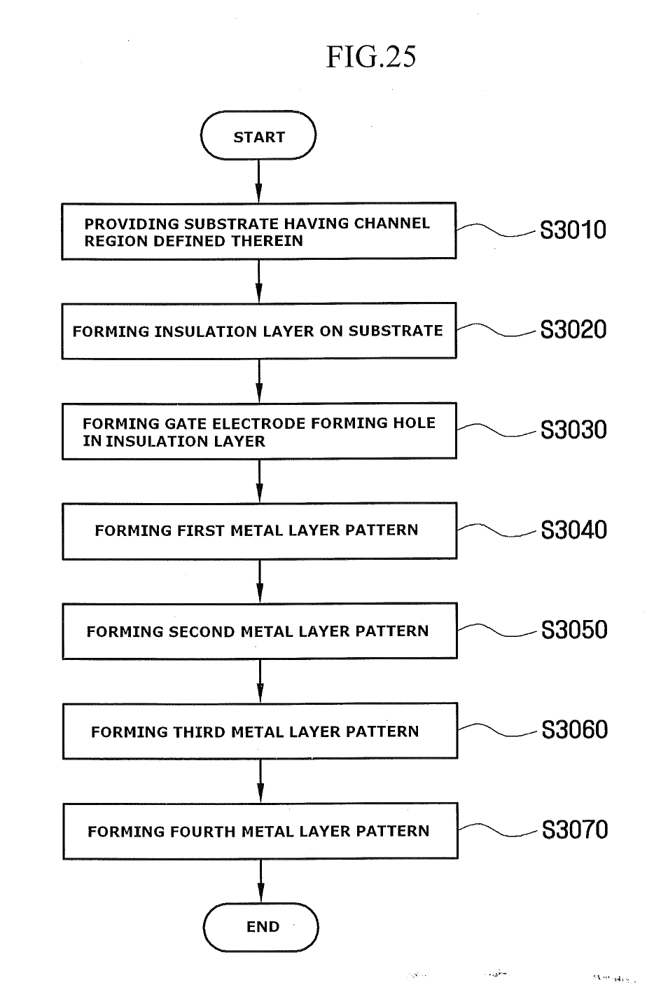

Processing steps in the fabrication of semiconductor devices according some embodiments of the present inventive concept will be discussed with respect to FIGS. 23 and 25. FIG. 23 is a cross-section of a semiconductor device according to some embodiments of the present inventive concept and FIG. 25 is a flowchart illustrating a processing steps in the fabrication of semiconductor devices in accordance with some embodiments of the present inventive concept. For the sake of convenient explanation, the same reference numerals refer to the same elements throughout and, therefore, details thereof will not be repeated in the interest of brevity. The processing steps in the fabrication of semiconductor devices according to these embodiments of the present inventive concept are substantially similar to those discussed above.

In particular, referring to FIG. 25, the processing steps S3010 to S3060 are substantially the same as S2010 to S2060 discussed above. As illustrated in FIGS. 23 and 25, the semiconductor device 5 may include a semiconductor substrate 100, a source region 111, a drain region 113, a channel region 121, an insulation layer 201, a gate insulation layer 221, a capping layer 223 and a gate electrode 305. In the semiconductor device 5, the gate electrode 305 may include a first metal layer pattern 313, a second metal layer pattern 323 formed on the first metal layer pattern 313, a third metal layer pattern 315 formed on the second metal layer pattern 323, and a fourth metal layer pattern 325 formed on the third metal layer pattern 315. In other words, the fourth metal layer pattern 325 may be formed on the third metal layer pattern 315 (S3070). In these embodiments, the first metal layer pattern 313, the second metal layer pattern 323 and the third metal layer pattern 315 are substantially the same as the first metal layer pattern 312, the second metal layer pattern 322 and the third metal layer pattern 314 discussed above.

The fourth metal layer pattern 325 may be conformally formed on the second and third metal layer patterns 323 and 315. Thus, the fourth metal layer pattern 325 may also be formed on the second metal layer pattern 323 on the edge portion (205b of FIG. 6) in the gate electrode trench 205. Accordingly, the likelihood of a gate edge thinning phenomenon in which an edge of the gate electrode 305 is thinned in the gate electrode trench 205 can be reduces, or possibly prevented. The fourth metal layer pattern 325 may be formed of titanium nitride (TiN) through a CVD process.

Processing steps in the fabrication of semiconductor devices in accordance with some embodiments of the present inventive concept will be discussed with respect to FIGS. 24 and 25. FIG. 24 is a cross-section of a semiconductor device according to some embodiments of the present inventive concept, and FIG. 25 is a flowchart illustrating processing steps of semiconductor devices according to some embodiments of the present inventive concept. For the sake of convenient explanation, the same reference numerals refer to like elements throughout and, therefore, the details of these elements will not be repeated herein in the interest of brevity.

Referring to FIG. 25, the processing steps S3010 to S3050 are substantially the same as S2010 to S2050 discussed above.

Referring to FIGS. 24 and 25, the semiconductor device 6 may include a semiconductor substrate 100, a source region 111, a drain region 113, a channel region 121, an insulation layer 201, a gate insulation layer 221, a capping layer 223 and a gate electrode 405. In the semiconductor device 6, the gate electrode 405 may include a first metal layer pattern 413, a second metal layer pattern 423 formed on the first metal layer pattern 413, a third metal layer pattern 415 formed on the second metal layer pattern 423, and a fourth metal layer pattern 425 formed on the third metal layer pattern 415. In other words, the fourth metal layer pattern 425 may be formed on the third metal layer pattern 415 (S3070). In these embodiments, the first metal layer pattern 413, the second metal layer pattern 423 and the third metal layer pattern 415 are substantially the same as first metal layer pattern 412, the second metal layer pattern 422 and the third metal layer pattern 414 discussed above, respectively.

The fourth metal layer pattern 425 may be formed on the third metal layer pattern 415 using, for example, titanium nitride (TiN), through a PVD process. The fourth metal layer pattern 425 may have a work function of the semiconductor device 6 according to the design rule. The work function of the semiconductor device 6 may determine a threshold voltage of a transistor. As a work function is closer to a band edge, an amount of dopant implanted into the channel region 121 is reduced, thereby increasing carrier mobility. Consequently, the overall operating characteristics of a transistor in the semiconductor device 6 can be improved.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the inventive concept.

What is claimed is:

1. A method of fabricating a semiconductor device, the method comprising:
providing a substrate having a channel region defined therein;
forming an insulation layer on the substrate;
forming a gate electrode trench having a sidewall portion, a bottom portion and an edge portion between the sidewall portion and the bottom portion on the insulation layer, the gate electrode trench being on the channel region; and
forming a gate electrode in the gate electrode trench, wherein forming the gate electrode comprises forming a first metal layer pattern in the gate electrode trench and forming a second metal layer pattern on the first metal layer pattern.

2. The method of claim 1, wherein forming the insulation layer is preceded by:
forming a dummy gate pattern on the substrate so as to overlap the channel region; and
forming a source region on a first side of the dummy gate pattern and a drain region on a second side of the dummy gate pattern.

3. The method of claim 2, wherein forming the gate electrode trench comprises removing the dummy gate pattern.

4. The method of claim 1, wherein the first metal layer pattern has a first thickness on the bottom portion and a second thickness on the edge portion, the first thickness being greater than the second thickness.

5. The method of claim 4, wherein forming the first metal layer pattern comprises forming the first metal layer pattern using physical vapor deposition (PVD).

6. The method of claim 4, wherein forming the second metal layer pattern comprises forming the second metal layer pattern conformally on the sidewall portion, the bottom portion and the edge portion.

7. The method of claim 6, wherein forming the second metal layer pattern comprises forming the second metal layer pattern using one of chemical vapor deposition (CVD) and atomic layer deposition (ALD).

8. The method of claim 6, wherein a thickness of the second metal layer pattern is greater than the second thickness on the edge portion.

9. The method of claim 1, wherein forming the first metal layer pattern comprises forming the first metal layer pattern conformally on the sidewall portion, the bottom portion and the edge portion.

10. The method of claim 9, wherein forming the first metal layer pattern comprises forming the first metal layer pattern using one of chemical vapor deposition (CVD) and atomic layer deposition (ALD).

11. The method of claim 10, wherein forming the second metal layer pattern comprises forming the second metal layer pattern using physical vapor deposition (PVD).

12. A method of fabricating a semiconductor device, the method comprising:
providing a substrate having a channel region defined therein;
forming a dummy gate pattern on the substrate on the channel region;
forming a source region on a first side of the dummy gate pattern and a drain region on a second side of the dummy gate pattern;
forming an insulation layer on the substrate so as to cover the source region and the drain region;
forming a gate electrode trench having a sidewall portion, a bottom portion and an edge portion between the sidewall portion and the bottom portion in the insulation layer by removing the dummy gate pattern, the gate electrode trench overlapping the channel region; and
forming a gate electrode in the gate electrode trench,
wherein forming a gate electrode comprises forming a first metal layer pattern in the gate electrode trench, forming a second metal layer pattern on the first metal layer pattern and forming a third metal layer pattern on the second metal layer pattern.

13. The method of claim 12:
wherein forming the first metal layer pattern and forming the third metal layer pattern comprises forming the first and third metal layer patterns using a same deposition process; and
wherein forming the second metal layer pattern comprises forming the second metal layer pattern using a different deposition method process than the same deposition process used to form the first metal layer pattern and the third metal layer pattern.

14. The method of claim 13:
wherein forming the first and third metal layer patterns comprises forming the first and third metal layer patterns using physical vapor deposition (PVD); and
wherein forming the second metal layer pattern comprises forming the second metal layer pattern using one of chemical vapor deposition (CVD) and atomic layer deposition (ALD).

15. The method of claim 13:
wherein forming the first and third metal layer patterns comprises forming the first and third metal layer patterns using one of chemical vapor deposition (CVD) and atomic layer deposition (ALD); and
wherein forming the second metal layer pattern comprises forming the second metal layer pattern using physical vapor deposition (PVD).

16. The method of claim 12, further comprising forming a fourth metal layer pattern on the third metal layer pattern.

17. The method of claim 16, wherein forming the fourth metal layer pattern comprises forming the fourth metal layer pattern using a deposition process that is substantially the same as a deposition process used to form the second metal layer pattern.

18. A method of fabricating a semiconductor device, the method comprising:
providing a substrate having a channel region defined therein;
forming a dummy gate pattern on the substrate on the channel region;
forming a source region on a first side of the dummy gate pattern and a drain region on a second side of the dummy gate pattern;
forming an insulation layer on the substrate so as to cover the source and drain regions;
forming a gate electrode trench having a sidewall portion, a bottom portion and an edge portion between the sidewall portion and the bottom portion on the insulation layer by removing the dummy gate pattern, the gate electrode trench overlapping the channel region; and
forming a gate electrode in the gate electrode trench,
wherein forming the gate electrode comprises forming a first metal layer pattern in the gate electrode trench by one of physical vapor deposition (PVD), chemical vapor deposition (CVD) and atomic layer deposition (ALD), and forming a second metal layer pattern on the first metal layer pattern using one of PVD, CVD and ALD.

19. The method of claim 18, further comprising forming a third metal layer pattern on the second metal layer pattern using one of PVD, CVD and ALD.

20. The method of claim 19, further comprising forming a fourth metal layer pattern on the third metal layer pattern using one of PVD, CVD and ALD.
